(19) United States
(12) Patent Application Publication
(10) Pub. No.: US 2025/0351432 A1
(43) Pub. Date: Nov. 13, 2025

(54) POWER SEMICONDUCTOR DEVICE AND POWER CONVERTOR INCLUDING THE SAME

(71) Applicants: LX SEMICON CO., LTD., Daejeon (KR); THE RESEARCH FOUNDATION FOR THE STATE UNIVERSITY OF NEW YORK, Albany, NY (US)

(72) Inventors: Hojung LEE, Daejeon (KR); Dongyoung KIM, Garland, TX (US); Jingon KIM, Daejeon (KR); Woongje SUNG, Niskayuna, NY (US); Chungkwang LEE, Daejeon (KR); Seung Yup JANG, Cohoes, NY (US)

(73) Assignees: LX SEMICON CO., LTD., Daejeon (KR); THE RESEARCH FOUNDATION FOR THE STATE UNIVERSITY OF NEW YORK, Albany, NY (US)

(21) Appl. No.: 19/207,074

(22) Filed: May 13, 2025

Related U.S. Application Data
(60) Provisional application No. 63/646,119, filed on May 13, 2024.

(30) Foreign Application Priority Data
May 13, 2025 (KR) 10-2025-0062151

(51) Int. Cl. H10D 30/66; H02M 7/493; H10D 62/10; H10D 62/60

(52) U.S. Cl. CPC H10D 30/668; H02M 7/493; H10D 62/102; H10D 62/124; H10D 62/60

(57) ABSTRACT

A power semiconductor device according to an embodiment may include a substrate on a drain electrode, a first epi layer of a first conductivity type disposed on the substrate, a second epi layer of the first conductivity type disposed on the first epi layer, a first well of the second conductivity type disposed on the second epi layer, a source region of the first conductivity type disposed on the first well of the second conductivity type, a gate insulating layer disposed to penetrate from the source region of the first conductivity type to a part of the second epi layer of the first conductivity type and forming a trench region therein, a trench gate disposed in the trench region, and an extended second well of the second conductivity type disposed in the second epi layer of the first conductivity type under the gate insulating layer.

### CROSS-REFERENCE TO RELATED APPLICATIONS

The present application claims the priorities of U.S. Patent Application No. 63/646,119, filed on May 13, 2024 and Korean Patent Application No. 10-2025-0062151, filed on May 13, 2025, both of which are hereby incorporated by reference in their entirety.

### BACKGROUND

### Field of the Disclosure

The embodiment relates to a power semiconductor device, a power semiconductor module, a power convertor, and a manufacturing method thereof.

### Description of the Background

Power semiconductors are one of the key elements that determine the efficiency, speed, durability, and reliability of power electronics systems.

Recently, with the development of the power electronics industry, research on WBG (Wide Bandgap) power semiconductors such as silicon carbide (SiC) and gallium nitride (GaN) to replace silicon (Si) power semiconductors is being actively conducted.

The WBG power semiconductor devices have a band gap energy about three times that of Si power semiconductor devices, and as a result, the WBG power semiconductor devices have the characteristics of low intrinsic carrier concentration, high dielectric breakdown field (about 4 to 20 times), high thermal conductivity (about 3 to 13 times), and large electron saturation velocity (about 2 to 2.5 times).

Due to these characteristics, the WBG power semiconductor devices can operate in high temperature and high voltage environments and have high switching speed and low switching loss. Among WBG power semiconductor devices, gallium nitride (GaN) power semiconductor devices may be used in low voltage systems, and silicon carbide (SiC) power semiconductor devices may be suitable for high voltage systems.

Conventional SiC MOSFET power semiconductors are generally expressed as VDMOSFETs with vertical diffused structures, and may also be simply expressed as double-diffused structure DMOSFETs. In addition, SiC MOSFETs may be classified into Planar MOSFETs and Trench MOSFETs depending on the direction of the channel.

Among these, Trench MOSFETs have a structure in which a channel is formed on the trench sidewall, and for this purpose, a gate insulating film is formed on the trench sidewall and a gate electrode is formed in the trench.

SiC MOSFETs have high On-resistance (Ron) due to low channel mobility and large channel resistance. For this reason, trench MOSFETs were proposed to lower the On-resistance (Ron). Trench MOSFETs have the advantage of increasing channel density by forming a channel on the trench sidewall.

However, trench MOSFETs have a larger electric field in the trench gate oxide, which has a shorter drift distance than P-base or P-well. In particular, since the electric field is concentrated at the trench edge, the breakdown of the gate oxide film occurs quickly, which causes a problem of a decrease in the breakdown voltage (BV).

For example, in the case of SiC Trench MOSFETs, since the breakdown field strength is 10 times that of Si MOSFETs, SiC semiconductor devices are used with a voltage that is nearly 10 times that of Si devices. Because of this, the gate insulating film formed in the trench is also subject to an electric field that is 10 times that of silicon devices, which causes the gate insulating film to be easily broken at the corners of the trench.

Meanwhile, in internal comparative technology, research has been conducted to place a bottom P-well under the trench to prevent electric field concentration at the trench corners of SiC Trench MOSFETs.

However, even if the bottom P-well structure is adopted, there is a problem of a low breakdown voltage (BV) due to ‘Reach Through’.

Even if a bottom P-well structure is adopted, there is a problem that the breakdown voltage may be lowered due to ‘Reach Through’, a phenomenon in which an edge of the depletion boundary comes into contact with a junction of another type that is heavily doped as the drain-source voltage increases, resulting in breakdown.

In addition, even though the bottom P-well for preventing electric field concentration at the trench corner contributes to preventing a drop in the breakdown voltage, there is a technical contradiction in which the On-resistance (Ron) increases due to the bottom P-well.

SUMMARY

One of the technical objects of the embodiment is to solve the problem of a decrease in the breakdown voltage due to Reach Through.

Also, one of the technical objects of the embodiment is to prevent the bottom P-well from concentrating electric fields at the corners of the trench while preventing the On-resistance from increasing.

The technical objects of the embodiment are not limited to those described in this item, and include those that may be understood through the description of the invention.

A power semiconductor device according to an embodiment may include a substrate on a drain electrode, a first epi layer of a first conductivity type disposed on the substrate, a second epi layer of a first conductivity type disposed on the first epi layer of the first conductivity type, a first well of a second conductivity type disposed on the second epi layer of the first conductivity type, a source region of the first conductivity type disposed on the first well of the second conductivity type, a gate insulating layer disposed to penetrate from the source region of the first conductivity type to a part of the second epi layer of the first conductivity type and form a trench region therein, a trench gate disposed in the trench region, and an extended second well of a second conductivity type disposed in the second epi layer of the first conductivity type below the gate insulating layer to a width equal to or greater than the trench region.

In addition, the embodiment may further include a contact region of the second conductivity type (123) disposed on the first well of the second conductivity type.

The extended second well of the second conductivity type (124E) may be doped with a concentration lower than or equal to the contact region of the second conductivity type.

The extended second well of the second conductivity type may be disposed in a continuous form along the trench region.

The extended second well of the second conductivity type may be disposed to extend in the first direction horizontally to the first direction, which is the extension direction of the trench gate.

In addition, the embodiment may further include a high-concentration third well of the second conductivity type (125) disposed within the first well of the second conductivity type. The high-concentration third well of the second conductivity type (125) may be disposed at the bottom of the contact region of the second conductivity type.

The high-concentration third well of the second conductivity type may have a higher doping concentration than the contact region of the second conductivity type.

The high-concentration third well of the second conductivity type may be disposed to be spaced apart from the gate insulating layer and the trench gate.

In addition, the embodiment may further include an extended high-concentration fourth well of the second conductivity type (126) disposed at the bottom of the contact region of the second conductivity type (123).

The extended high-concentration fourth well of the second conductivity type (126) may be formed to extend to the first well of the second conductivity type and the epilayer of the first conductivity type.

The extended high-concentration fourth well of the second conductivity type (126) may have a higher doping concentration than the contact region of the second conductivity type (123).

The bottom end of the extended high-concentration fourth well of the second conductivity type (126) may be positioned lower than the bottom end of the first well of the second conductivity type (121).

In addition, the embodiment may further include an ion implantation connection region of the second conductivity type (121U) that is positioned to extend in the second direction perpendicular to the first direction while connecting the extended second well of the second conductivity type (124E) that is positioned horizontally in the first direction.

In addition, the power semiconductor device according to the embodiment may include a substrate on a drain electrode, a first epi layer of a first conductivity type disposed on the substrate, a second epi layer of the first conductivity type disposed on the first epi layer of the first conductivity type, a first well of a second conductivity type disposed on the second epi layer of the first conductivity type, a source region of the first conductivity type disposed on the first well of the second conductivity type, a gate insulating layer disposed to penetrate from the source region of the first conductivity type to a part of the second epi layer of the first conductivity type and form a trench region therein, a trench gate disposed in the trench region, a contact region of the second conductivity type disposed on the first well of the second conductivity type, and a deep fifth well of the second conductivity type disposed below the contact region of the second conductivity type and having a bottom end lower than a bottom of the trench region.

The deep fifth well of the second conductivity type (127) may include an extended deep fifth well of the second conductivity type (127P) extending from the bottom of the deep fifth well of the second conductivity type (127) to the trench region.

In addition, the power convertor according to the embodiment may include any one of the power semiconductor devices.

According to the power semiconductor device according to the embodiment and the power convertor including the same and the manufacturing method of the power semiconductor device, even when a bottom P-well structure is adopted, the problem of breakdown voltage reduction due to Reach Through can be solved.

For example, even if the embodiment adopts the bottom P-well structure, it can solve the problem of breakdown voltage reduction due to Reach Through, in which the edge of the depletion boundary comes into contact with a highly doped junction of another conductivity type as the drain-source voltage increases.

Specifically, referring to FIGS. 6 to 8, the first power semiconductor device (101) according to the embodiment may include a high-concentration third well of the second conductivity type (125) having a higher concentration than the contact region of the second conductivity type (123). Accordingly, BV (breakdown voltage) reduction due to Reach Through in the second-conductivity region that is not covered by the bottom P-well can be prevented.

Also, referring to FIG. 6, an extended second well of the second conductivity type (124E) may be disposed in a continuous form along the trench area wider than the width of the trench gate (132) on the lower side of the trench. Accordingly, the embodiment has a technical effect of dispersing an electric field concentrated on the trench corner to prevent a breakdown voltage drop of the gate insulation layer and improving the reliability of the gate insulation layer.

In addition, the extended second well of the second conductivity type (124E) may be disposed to overlap the contact area of the second conductivity type (123) between the upper and lower sides, and thus has a special technical effect of more effectively preventing Reach Through (RT).

Next, referring to FIG. 10, the second power semiconductor device (102) may include a first well of the second conductivity type (121) and an extended high-concentration fourth well of the second conductivity type (126) that is disposed to extend in the direction of the epi layer of the first conductivity type (110E). The extended high-concentration fourth well of the second conductivity type (126) may have a higher doping concentration than the contact region of the second conductivity type (123). Accordingly, according to the second power semiconductor device (102), by including an extended high-concentration fourth well of the second conductivity type (126) having a higher concentration than the contact region of the second conductivity type (123), the Reach Through BV degradation occurring in the second conductivity type region that is not covered by the lower P-well may be more effectively prevented.

In addition, the bottom of the extended high-concentration fourth well of the second conductivity type (126) may be positioned lower than the bottom of the first well of the second conductivity type (121). Accordingly, the extended high-concentration fourth well of the second conductivity type (126) may be formed deeper than the first well of the second conductivity type (121), thereby further improving the shielding capability.

In addition, referring to FIG. 13, in the embodiment, the ion implantation connection area of the second conductivity type (121U) may connect the extended second well of the second conductivity type (124E) and the first well of the second conductivity type (121). Accordingly, the first well of the second conductivity type (121) to which the ground potential is applied can be connected to the extended second well of the second conductivity type (124E) by the ion implantation connection area of the second conductivity type (121U), so that the ground potential can be also applied to the extended second well of the second conductivity type (124E).

Therefore, according to the embodiment, since the ground potential can be applied to the extended second well of the second conductivity type (124E) to prevent electric field concentration at the trench corner, there is a complex technical effect in that the occurrence of a depletion region in the extended second well of the second conductivity type (124E) can be prevented and the increase in the On-resistance (Ron) can be prevented.

In addition, since the ground potential can be applied to the extended second well of the second conductivity type (124E) to prevent electric field concentration at the trench corner, the extended second well of the second conductivity type (124E) is not made floating, so there is no charging and discharging phenomenon of the extended second well of the second conductivity type (124E), and thus there is a technical effect of enabling stable operation in a dynamic or switching situation.

The technical effect of the embodiment is not limited to what is described in this item, and may include what may be understood through the description of the invention.

### BRIEF DESCRIPTION OF THE DRAWINGS

The patent or application file contains at least one drawing executed in color. Copies of this patent or patent application publication with color drawing(s) will be provided by the

Office upon request and payment of the necessary fee.

FIG. 1 is a configuration example diagram of a power convertor (1000) according to an embodiment.

FIG. 2 is a cross-sectional view of a power semiconductor device (100) according to an embodiment.

FIG. 3 is a cross-sectional view of a power semiconductor device (100R) according to a comparative example.

FIG. 4 is experimental data of current flow of a power semiconductor device (100R) according to a comparative example.

FIG. 5 is experimental data of impact ionization of a power semiconductor device (100R) according to a comparative example.

FIG. 6 is a cross-sectional view of a first power semiconductor device (101) according to an embodiment.

FIG. 7 is experimental data of current flow (C) of a first power semiconductor device (101) according to an embodiment.

FIG. 8 is experimental data of impact ionization of a first power semiconductor device (101) according to an embodiment.

FIG. 9 is data of breakdown voltage of power semiconductor devices according to a comparative example and an embodiment.

FIG. 10 is a cross-sectional view of a second power semiconductor device (102) according to an embodiment.

FIG. 11 is an experimental data of current flow (C) of a second power semiconductor device (102) according to an embodiment.

FIG. 12 is an experimental data of impact ionization of a second power semiconductor device (102) according to an embodiment.

FIG. 13 is a cross-sectional view of a third power semiconductor device (103) according to an embodiment.

FIG. 14A is a cross-sectional view of a fourth power semiconductor device (104) according to an embodiment.

FIG. 14B is a cross-sectional view of a fifth power semiconductor device (105) according to an embodiment.

### DETAILED DESCRIPTION

Hereinafter, the invention according to an embodiment for solving the above problem will be described in more detail with reference to the drawings.

The suffixes “module” and “part” used for components in the following description are given simply for the convenience of writing this specification, and do not impart any particularly important meaning or role in themselves. Therefore, the “module” and “part” may be used interchangeably.

Terms including ordinal numbers such as first, second, etc. may be used to describe various components, but the components are not limited by the terms. The terms are used only for the purpose of distinguishing one component from another.

The singular expression may include the plural expression unless the context clearly indicates otherwise.

In this application, the terms “may include,” “has,” or “comprises” are intended to specify the presence of a feature, number, step, operation, component, part, or combination thereof described in the specification, and should be understood as not excluding in advance the possibility of the presence or addition of one or more other features, numbers, steps, operations, components, parts, or combinations thereof.

### Embodiment

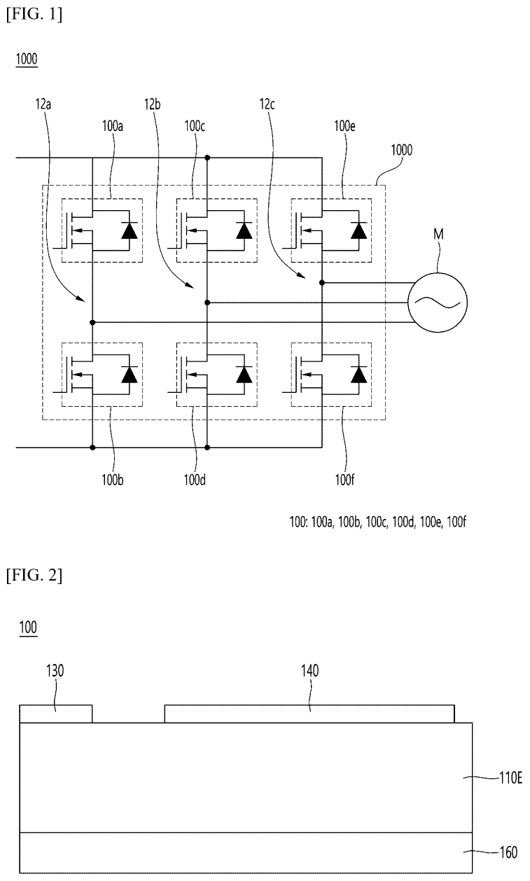

FIG. 1 is a configuration example diagram of a power convertor (1000) according to an embodiment.

The power convertor (1000) according to the embodiment may receive DC power from a battery or a fuel cell, convert it into AC power, and supply AC power to a predetermined load. For example, the power convertor (1000) according to the embodiment may include an inverter, and may receive DC power from a battery, convert it into three-phase AC power, and supply it to a motor (M), and the motor (M) may provide power to an electric vehicle, a fuel cell vehicle, etc.

The power convertor (1000) according to the embodiment may include a power semiconductor device (100). The power semiconductor device (100) may be a MOSFET (Metal Oxide Semiconductor Field Effect Transistor), but is not limited thereto, and may include an IGBT (Insulated Gate Bipolar Transistor).

For example, the power convertor (1000) may include a plurality of power semiconductor devices (100a, 100b, 100c, 100d, 100e, 100f) and may include a plurality of diodes (not shown). Each of the plurality of diodes may be embedded in the power semiconductor devices (100a, 100b, 100c, 100d, 100e, 100f) in the form of an internal diode, but is not limited thereto, and may be disposed separately.

The embodiment may convert DC power into AC power through on-off control for a plurality of power semiconductor devices (100a to 100f). For example, the power convertor (1000) according to the embodiment may supply positive power to the motor (M) by turning on the first power semiconductor device (100a) and turning off the second power semiconductor device (100b) in a first time section of one cycle, and supply negative power to the motor (M) by turning off the first power semiconductor device (100a) and turning on the second power semiconductor device (100b) in a second time section of one cycle.

In the embodiment, a group of power semiconductor devices disposed in series on the high-voltage line and the low-voltage line of the input side may be called an arm. For example, the first power semiconductor device (100a) and the second power semiconductor device (100b) may constitute the first arm (12a), the third power semiconductor device (100c) and the fourth power semiconductor device (100d) may constitute the second arm (12b), and the fifth power semiconductor device (100e) and the sixth power semiconductor device (100f) may constitute the third arm (12c).

In the arm, the upper power semiconductor device and the lower power semiconductor device may be controlled not to be turned on at the same time. For example, in the first arm, the first power semiconductor device (100a) and the second power semiconductor device (100b) may not be turned on at the same time but may be turned on and off alternately.

Each power semiconductor device (100a to 100f) may receive high power in an off state. For example, when the first power semiconductor device (100a) is turned on and the second power semiconductor device (100b) is turned off, the input voltage may be applied as it is to the second power semiconductor device (100b). The voltage input to the second power semiconductor device (100b) may be a relatively high voltage, and the withstand voltage of each power semiconductor device (100a to 100f) may be designed to be high so as to withstand this high voltage.

Each power semiconductor device (100a to 100f) may conduct a high current when turned on. The motor (M) is driven by a relatively high current, and this high current may be supplied to the motor (M) through the power semiconductor device that is turned on.

The high voltage applied to each power semiconductor device (100a to 100f) may cause a high switching loss such that power semiconductor devices (100a˜100f) may cause high conduction loss. In order to release the heat generated by this loss, the power semiconductor device (100a to 100f) may be packaged as a power semiconductor module including a heat dissipation means.

The power semiconductor device (100) of the embodiment may be a silicon carbide (SIC) power semiconductor device, and may operate in a high temperature and high voltage environment and may have a high switching speed and low switching loss.

Meanwhile, the power convertor (1000) according to the embodiment may include a plurality of power semiconductor modules.

For example, a plurality of power semiconductor devices (100a to 100f) illustrated in FIG. 1 may be packaged as one power semiconductor module, or the power semiconductor devices constituting each arm may be packaged as one power semiconductor module.

For example, the first power semiconductor device (100a), the second power semiconductor device (100b), the third power semiconductor device (100c), the fourth power semiconductor device (100d), the fifth power semiconductor device (100e), and the sixth power semiconductor device (100f) illustrated in FIG. 1 may be packaged as one power semiconductor module.

In addition, in order to increase the current capacity, there may be additional power semiconductor devices disposed in parallel with each power semiconductor device (100a to 100f). In this case, the number of power semiconductor devices included in the power semiconductor module may be more than six.

The power convertor (1000) according to the embodiment may also include a diode-type power semiconductor device in addition to the transistor-type power semiconductor devices (100a to 100f). For example, a first diode (not shown) may be disposed in parallel with a first power semiconductor device (100a), and a second diode (not shown) may be disposed in parallel with a second power semiconductor device (100b). In addition, these diodes may also be packaged together in one power semiconductor module. In addition, the diodes may be disposed in the form of internal diodes in each power semiconductor device.

Next, the power semiconductor devices constituting each arm may be packaged in one power semiconductor module.

For example, the first power semiconductor device (100a) and the second power semiconductor device (100b) constituting the first arm may be packaged as a first power semiconductor module, the third power semiconductor device (100c) and the fourth power semiconductor device (100d) constituting the second arm may be packaged as a second power semiconductor module, and the fifth power semiconductor device (100e) and the sixth power semiconductor device (100f) constituting the third arm may be packaged as a third power semiconductor module.

In addition, in order to increase the current capacity, there may be additional power semiconductor devices disposed in parallel with each power semiconductor device (100a to 100f), and in this case, the number of power semiconductor devices included in each power semiconductor module may be more than two. And, in addition to the transistor-type power semiconductor devices (100a to 100f), each arm may also include a diode-type power semiconductor device (not shown), and these diodes may also be packaged together in one power semiconductor module. In addition, the diode may be disposed in the form of an internal diode in each power semiconductor device.

Next, FIG. 2 is a cross-sectional view of one of the power semiconductor devices (100) according to the embodiment.

The power semiconductor device (100) according to the embodiment may include a source electrode (140), a gate electrode (130) disposed spaced apart from each other on the upper side of a predetermined semiconductor epi layer (110E), and a drain electrode (160) disposed on the lower side of the semiconductor epi layer (110E).

In the form of MOSFET, the source electrode (140) or the gate electrode (130) may include an Al based metal and may include a Ni layer, a Ti layer, a Ni/Ti layer, or a TiN/Ti silicide layer.

The drain electrode (160) may include a Ni based metal and may include a Ti layer, a Ni layer, or an Ag layer. For example, the drain electrode (160) may include Ti/Ag, Ti/Ni/Ag, NiV/Ag, V (vanadium)/Ni/Ag, etc., but is not limited thereto.

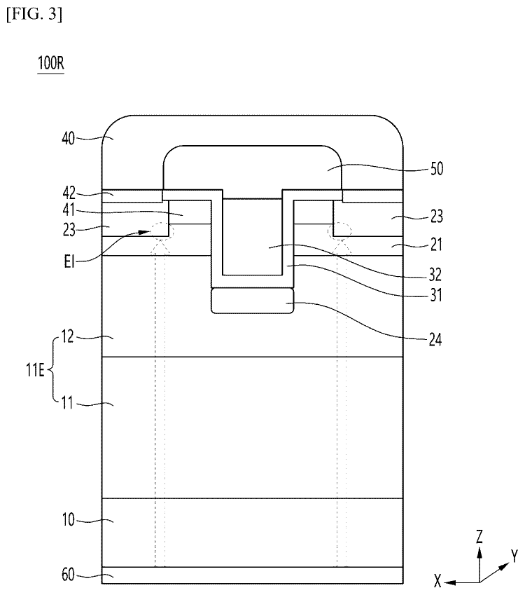

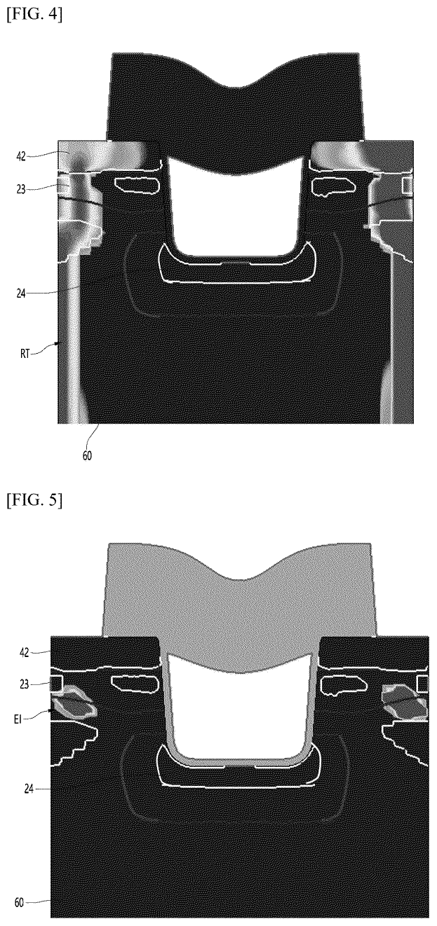

FIG. 3 is a cross-sectional view of a power semiconductor device (100R) according to a comparative example. FIG. 4 is experimental data of current flow of the power semiconductor device (100R) according to the comparative example, and FIG. 5 is experimental data of impact ionization of the power semiconductor device (100R) according to the comparative example. Also, FIG. 9 is breakdown voltage data of the power semiconductor device according to the comparative example and the embodiment.

First, referring to FIG. 3, the power semiconductor device (100R) according to the comparative example may include a drain electrode (60), a substrate (10), an epi layer (11E), a first well (21) of a second conductivity type, a contact region of the second conductivity type (23), a source region of a first conductivity type (41), a source contact region (42), a source electrode (40), a gate insulating layer (31), a trench gate (32), a second well of the second conductivity type (24), and an interlayer insulating layer (50). The epi layer (11E) may include a first epi layer of the first conductivity type (11) and a second epi layer of the first conductivity type (12). The above first conductivity type may be N type, and the second conductivity type may be P type, but is not limited thereto.

In the comparative technique, the lower edge area (EI) of the contact area of the second conductivity type (23) may be a vulnerable point for Reach Through (RT) BV degradation.

Specifically, even if the second well of the second conductivity type (24), which is a bottom P-well structure, is adopted in the comparative technique, there is a problem that the breakdown voltage due to Reach Through (RT) degradation occurs when the edge of the depletion boundary comes into contact with a junction of another type that is highly doped as the drain-source voltage increases.

Specifically, FIG. 4 is experimental data of current flow of the power semiconductor device (100R) according to the comparative example, and FIG. 5 is experimental data of impact ionization of the power semiconductor device (100R) according to the comparative example.

First, referring to FIG. 5, in the comparative example, as the drain-source voltage increases in the lower edge region (EI) of the contact region of the second conductivity type (23), impact ionization may occur in which electrons accelerated by an electric field collide with atoms to generate electron-hole pairs.

Accordingly, even if the second well of the second conductivity type (24), which is a bottom P-well structure as shown in FIG. 4, is adopted, there is a problem that the breakdown voltage due to Reach Through (RT) is lowered as the drain-source voltage increases, where the edge of the depletion boundary comes into contact with the junction of another type that is highly doped, and a breakdown may occur.

Referring briefly to FIG. 9, the comparative example (R) shows a low BV of about 45 V due to the RT (Reach Through) BV.

Accordingly, one of the technical objects of the embodiment is to solve the problem of the breakdown voltage lowered due to Reach Through.

In addition, one of the technical objects of the embodiment is to prevent the electric field concentration at the trench corner by the bottom P-well while preventing the On-resistance from increasing.

Hereinafter, the technical features of the embodiment for solving the above technical problems will be described.

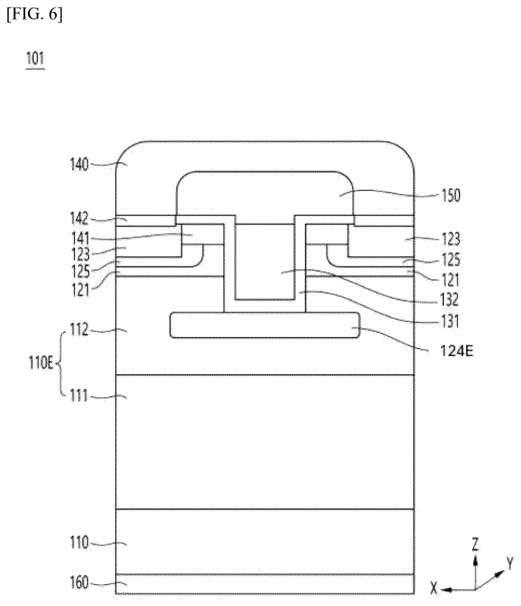

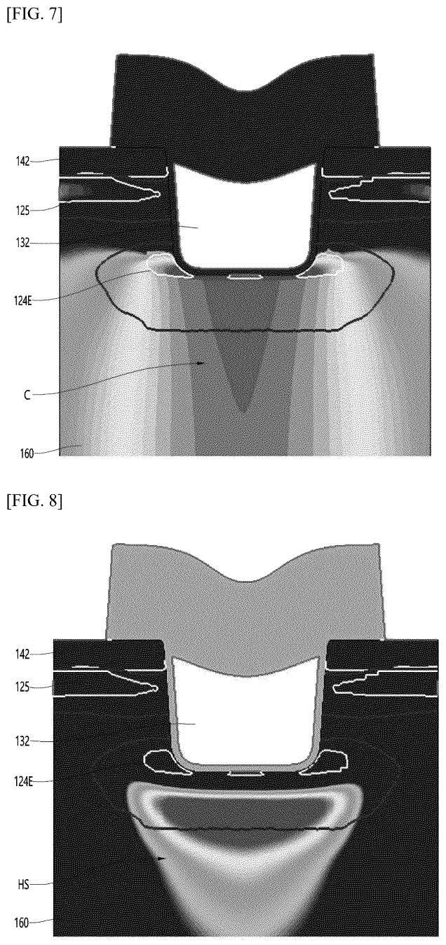

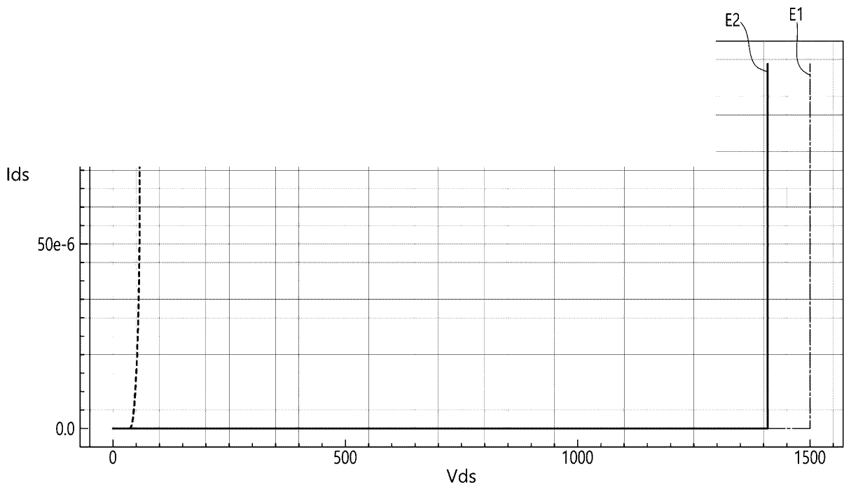

FIG. 6 is a cross-sectional view of the first power semiconductor device (101) according to the embodiment. FIG. 7 is experimental data of the current flow (C) of the first power semiconductor device (101) according to the embodiment, and FIG. 8 is experimental data of the impact ionization of the first power semiconductor device (101) according to the embodiment. In addition, FIG. 9 is breakdown voltage data of the power semiconductor device according to the comparative example and the embodiment.

The first power semiconductor device (101) according to the embodiment may include at least one of a drain electrode (160), a substrate (110), an epi layer (110E), a first well of the second conductivity type (121), a contact region of the second conductivity type (123), a high-concentration third well of the second conductivity type (125), a source region of the first conductivity type (141), a source contact region (142), a source electrode (140), a gate insulating layer (131), a trench gate (132), an extended second well of the second conductivity type (124E), and an interlayer insulating layer (150).

The epi layer (110E) may include a first epi layer of the first conductivity type (111) and a second epi layer of the first conductivity type (112). The first conductivity type may be N-type, and the second conductivity type may be P-type, but is not limited thereto. For example, the N-type dopant may be injected with nitrogen (N) or phosphorus (P), but is not limited thereto. In addition, the P-type dopant may be injected with aluminum (Al) or boron (B), but is not limited thereto.

Specifically, referring to FIG. 6, the first power semiconductor device (101) according to the embodiment may include a substrate (110), a first epi layer of the first conductivity type (111) disposed on the substrate (110), and a second epi layer of the first conductivity type (112) disposed on the first epi layer of the first conductivity type (111).

The substrate (110), the first epi layer of the first conductivity type (111), and the second epi layer of the first conductivity type (112) may include SiC (Silicon Carbide) and may be doped with an N type, but is not limited thereto. For example, the substrate (110) and the first and second epi layers of the first conductivity type (111, 112) may include a 4H-SiC material, but is not limited thereto. For example, the substrate (110) and the first and second epi layers of the first conductivity type (111, 112) may include 3C-SiC or 6H-SiC.

The first epi layer of the first conductivity type (111) may include a buffer layer (not shown) of the first conductivity type and a drift layer of the first conductivity type (not shown). The first epi layer of the first conductivity type (111) may prevent a drop in breakdown voltage (VB) by being doped at a lower concentration than the substrate (110).

In addition, the second epi layer of the first conductivity type (112) may lower the On-resistance by functioning as a current spreading layer (CSL) by being doped at a higher concentration than the first epi layer of the first conductivity type (111).

The first well of the second conductivity type (121) may be formed by ion implantation of a second-conductivity type dopant into the second epi layer of the first conductivity type (112) or growth of a second conductivity type epi layer. The first well of the second conductivity type (121) may be referred to as a second conductivity type base layer, but is not limited thereto.

The source region of the first conductivity type (141) and the contact region of the second conductivity type (123) may be formed by ion implantation into the first well of the second conductivity type (121).

The doping concentration of the source region of the first conductivity type (141) and the contact region of the second conductivity type (123) may be higher than that of the first well of the second conductivity type (121). The contact region of the second conductivity type (123) may be formed partially. The contact region of the second conductivity type (123) may have a function of maintaining the zero potential of the first well of the second conductivity type (121).

In addition, the first power semiconductor device (101) of the embodiment may include a high-concentration third well of the second conductivity type (125).

The high-concentration third well of the second conductivity type (125) may be formed within the first well of the second conductivity type (121) and may be disposed at the bottom of the contact region of the second conductivity type (123).

The high-concentration third well of the second conductivity type (125) may have a higher doping concentration than the contact region of the second conductivity type (123).

The embodiment can solve the problem of breakdown voltage reduction due to Reach Through, in which the edge of the depletion boundary comes into contact with another type of junction that is highly doped as the drain-source voltage increases, even if a bottom P-well structure is adopted.

Specifically, the first power semiconductor device (101) according to the embodiment may include a high-concentration third well of the second conductivity type (125) having a higher concentration than the contact region of the second conductivity type (123). Accordingly, BV degradation due to Reach Through can be prevented in the second conductivity type region not covered by the lower P-well.

In addition, the high-concentration third well of the second conductivity type (125) may be disposed to be spaced apart from the gate insulating layer (131) and the trench gate (132), thereby preventing the high-concentration third well of the second conductivity type (125) having a high concentration from affecting the Vth.

First, referring to FIG. 8, in the first power semiconductor device (101) according to the embodiment, a high-concentration third well of the second conductivity type (125) having a higher concentration than the contact region of the second conductivity type (123) may be included in the lower edge region of the contact region of the second conductivity type (123). Accordingly, in the embodiment, impact ionization (HS), in which electrons and atoms accelerated by an electric field collide to generate electron-hole pairs as the drain-source voltage increases, may be formed on the lower side of the trench gate (132).

Accordingly, as shown in FIG. 7, Reach Through (RT), in which breakdown occurs when the edge of the depletion boundary comes into contact with a junction of another type that is highly doped as the drain-source voltage increases, can be prevented, and current flow (C) may occur through the lower side of the trench gate (132).

Accordingly, referring to FIG. 9, in the first power semiconductor device (E1) according to the embodiment, no RT (Reach Through) BV occurs and a very high BV of about 1497 V is shown.

Referring again to FIG. 6, the gate insulating layer (131) may be formed on the bottom and side walls of the trench region from which the source region of the first conductivity type (141), the first well of the second conductivity type (121), and a portion of the epi layer of the second conductivity type (112) are removed by a thermal oxidation or deposition process.

Next, the trench gate (132) may be formed on the trench on the gate insulating layer (131) by a polysilicon deposition process and an etch back process.

Next, the source contact region (142) may be formed as the source region of the first conductivity type (141) and/or the contact region of the second conductivity type (123). For example, the source contact region (142) may be formed using Ti or Ni, but is not limited thereto.

Next, the interlayer insulating layer (150) may be formed on the trench gate (132) by a deposition process of an oxide film or the like.

Next, the source electrode (140), the gate electrode (not shown), and the drain electrode (160) may be formed.

For example, the source electrode (140) or the gate electrode (130) may include an Al-based metal, and may include a Ni layer, a Ti layer, a Ni/Ti layer, or a TiN/Ti silicide layer. In addition, the drain electrode (160) may include an Ni-based metal, and may include a Ti layer, a Ni layer, and an Ag layer. For example, the drain electrode (160) may include, but is not limited to, Ti/Ag, Ti/Ni/Ag, NiV/Ag, V (vanadium)/Ni/Ag, etc.

Next, the embodiment may include an extended second well of the second conductivity type (124E) disposed on a second epilayer of the first conductivity type (112) under the gate insulating layer (131).

The extended second well of the second conductivity type (124E) is disposed on the lower side of the trench, and may be doped at a concentration lower than or equal to the contact region of the second conductivity type (123), but is not limited thereto.

The extended second well of the second conductivity type (124E) may be disposed on the lower side of the trench, and may be disposed in a continuous form along the trench region.

The extended second well of the second conductivity type (124E) may be formed by high-energy ion implantation or by using a re-growth process. For example, the extended second well of the second conductivity type (124E) may be formed by high-energy ion implantation after the second epi layer of the first conductivity type (112) is grown on the first epi layer of the first conductivity type (111). Alternatively, the extended second well of the second conductivity type (124E) may be formed by ion implantation after the first epi layer of the first conductivity type (111) is formed, and then the second epi layer of the first conductivity type (112) may be formed.

The extended second well of the second conductivity type (124E) may be disposed to extend horizontally in the first direction (Y) of the trench gate (132), which is the extension direction of the trench gate (132).

According to the power semiconductor device and the power convertor including the same and the manufacturing method of the power semiconductor device according to the embodiment, there is a technical effect of solving the problem of increasing of On-resistance (Ron) or the problem of adversely affecting the electrical characteristics of the power semiconductor device while preventing electric field concentration at the trench corner.

For example, according to the embodiment, the extended second well of the second conductivity type (124E) may be disposed in a continuous form along the trench area wider than the width of the trench gate (132) at the lower side of the trench, thereby dispersing the electric field concentrated at the trench corner. There is a technical effect of preventing the breakdown voltage drop of the gate insulation layer and improving the reliability of the gate insulation layer.

In addition, the extended second well of the second conductivity type (124E) may be disposed to overlap the contact region of the second conductivity type (123) disposed at the lower edge region of the contact region of the second conductivity type (123) between the upper and lower sides such that the embodiment can have a special technical effect of more effectively preventing Reach Through (RT).

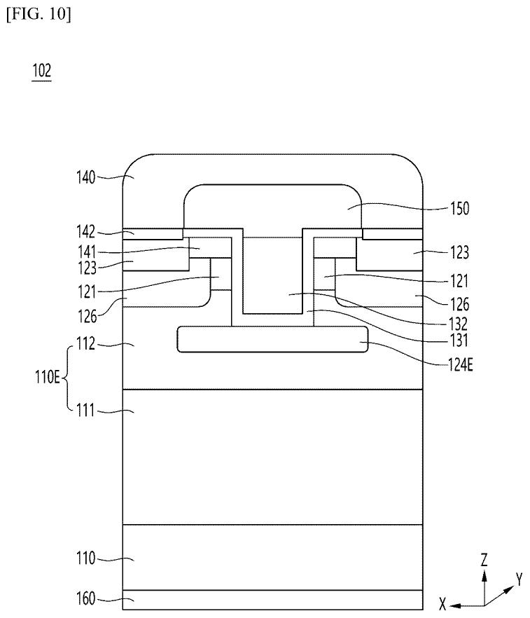

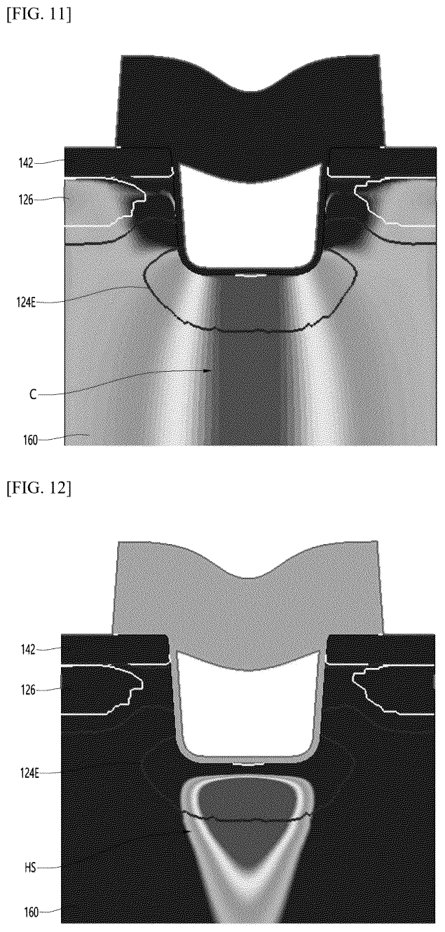

Next, FIG. 10 is a cross-sectional view of a second power semiconductor device (102) according to an embodiment, FIG. 11 is experimental data of current flow (C) of the second power semiconductor device (102) according to an embodiment, and FIG. 12 is experimental data of impact ionization of the second power semiconductor device (102) according to an embodiment. In addition, FIG. 9 is breakdown voltage data of a power semiconductor device according to a comparative example and an embodiment.

The second power semiconductor device (102) according to the embodiment may adopt the technical features of the first power semiconductor device (101), and the main features of the second power semiconductor device (102) will be described below.

Referring to FIG. 10, the second power semiconductor device (102) according to the embodiment may include at least one of a drain electrode (160), a substrate (110), a epi layer of the first conductivity type (110E), a first well of the second conductivity type (121), a contact region of the second conductivity type (123), an extended high-concentration fourth well of the second conductivity type (126), a source region of the first conductivity type (141), a source contact region (142), a source electrode (140), a gate insulating layer (131), a trench gate (132), an extended second well of the second conductivity type (124E), and an interlayer insulating layer (150).

Compared to the first power semiconductor device (101), the second power semiconductor device (102) may include an extended high concentration fourth well of the second conductivity type (126). The extended high concentration fourth well of the second conductivity type (126) may be formed by extending to the first well of the second conductivity type (121) and the epi layer of the first conductivity type (110E), and may be disposed at the bottom of the contact region of the second conductivity type (123).

The extended high concentration fourth well of the second conductivity type (126) may have a higher doping concentration than the contact region of the second conductivity type (123).

The second power semiconductor device (102) may include an extended high-concentration fourth well of the second conductivity type (126) having higher concentration than the contact region of the second conductivity type (123). Accordingly, Reach Through BV occurring in the region of second conductivity type where the lower P-well does not cover may be more effectively prevented.

In addition, the bottom end of the extended high-concentration fourth well of the second conductivity type (126) may be positioned lower than the bottom end of the first well of the second conductivity type (121). Accordingly, the extended high-concentration fourth well of the second conductivity type (126) may be formed deeper than the first well of the second conductivity type (121), thereby further improving the shielding capability.

In addition, the extended high-concentration fourth well of the second conductivity type (126) may be disposed apart from the gate insulating layer (131) and the trench gate (132), thereby preventing the extended high-concentration fourth well of the second conductivity type (126) having a high concentration from affecting the Vth.

Specifically, referring to FIG. 12, in the second power semiconductor device (102) according to the embodiment, the extended high-concentration fourth well of the second conductivity type (126) having a higher concentration than the contact region of the second conductivity type (123) may be included in the lower edge region of the contact region of the second conductivity type (123). Accordingly, in the second power semiconductor device (102), the impact ionization (HS) in which electrons and atoms accelerated by the electric field collide to generate electron-hole pairs as the drain-source voltage increases may be formed on the lower side of the trench gate (132).

Accordingly, as shown in FIG. 11, as the drain-source voltage increases, the Reach

Through (RT) and breakdown occurring can be prevented, and a current flow (C) may occur through the lower side of the trench gate (132).

Referring to FIG. 9, in the second power semiconductor device (E2) according to the embodiment, the RT (Reach Through) BV does not occur, and a very high BV of about 1409 V is shown.

Referring back to FIG. 10, the second power semiconductor device (102) of the embodiment may include an extended second well of the second conductivity type (124E) disposed on the second epi layer of the first conductivity type (112) under the gate insulating layer (131). The extended second well of the second conductivity type (124E) is disposed on the lower side of the trench and may be doped at a concentration lower than or equal to the contact region of the second conductivity type (123), but is not limited thereto.

The extended second well of the second conductivity type (124E) may be disposed on the lower side of the trench and may be disposed in a continuous form along the trench region. The extended second well of the second conductivity type (124E) may be formed by high-energy ion implantation or by using a re-growth process. For example, after the first epi layer of the first conductivity type (111) is grown to the second epi layer of the first conductivity type (112), the second well of the second conductivity type (124E) may be formed by high energy ion implantation. Alternatively, after the first epi layer of the first conductivity type (111) is formed, the second well of the second conductivity type (124E) may be formed by ion implantation, and then the second epi layer of the first conductivity type (112) may be formed.

The second well of the second conductivity type (124E) may be disposed to extend in the first direction (Y) horizontally to the first direction (Y), which is the extension direction of the trench gate (132).

According to the power semiconductor device and the power convertor including the same and the manufacturing method of the power semiconductor device according to the embodiment, there is a technical effect that can solve the problem of increasing of On-resistance (Ron) or the problem of adversely affecting the electrical characteristics of the power semiconductor device while preventing electric field concentration at the trench corner.

For example, according to the embodiment, since the extended second well of the second conductivity type (124E) is continuously disposed along the trench area wider than the width of the trench gate (132) at the lower side of the trench, the electric field concentrated at the trench corner can be dispersed, thereby preventing the breakdown voltage drop of the gate insulation layer and improving the reliability of the gate insulation layer.

In addition, the extended second well of the second conductivity type (124E) may be disposed to overlap the contact area of the second conductivity type (123) disposed at the lower edge area of the contact area of the second conductivity type (123) between the upper and lower sides, thereby providing a special technical effect of more effectively preventing Reach Through (RT).

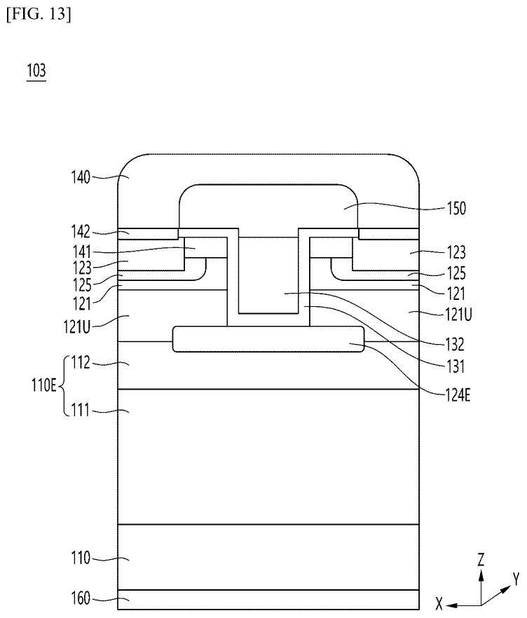

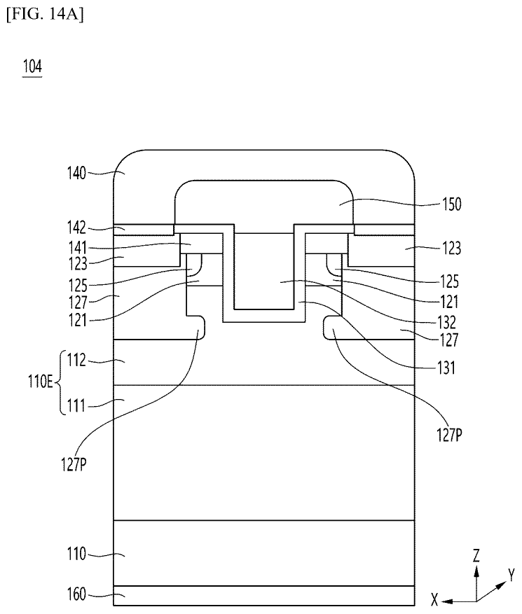

Next, FIG. 13 is a cross-sectional view of a third power semiconductor device (103) according to an embodiment.

The third power semiconductor device (103) according to an embodiment may adopt the technical features of the first power semiconductor device (101) and the second power semiconductor device (102), and the main features of the third power semiconductor device (103) will be described below.

The third power semiconductor device (103) according to the embodiment may include at least one of a drain electrode (160), a substrate (110), an epi layer (110E), a first well of the second conductivity type (121), a contact region of the second conductivity type (123), a high concentration third well of the second conductivity type (125), a source region of the first conductivity type (141), a source contact region (142), a source electrode (140), a gate insulating layer (131), a trench gate (132), an extended second well of the second conductivity type (124E), and an interlayer insulating layer (150).

The third power semiconductor device (103) according to the embodiment may include an ion implantation connection region of a second conductivity type (121U).

The ion implantation connection region of the second conductivity type (121U) may be disposed to extend in the second direction (X) perpendicular to the first direction (Y) which is the extension direction of the trench gate (132).

The ion implantation connection region of the second conductivity type (121U) may be disposed to extend in the second direction (X) perpendicular to the first direction (Y) while connecting the extended second well of the second conductivity type (124E), which is disposed horizontally in the first direction (Y), while being spaced apart in the first direction (Y).

The upper end of the ion implantation connection region of the second conductivity type (121U) may be disposed higher than the bottom end of the gate insulating layer (131), and the bottom end of the ion implantation connection region of the second conductivity type (121U) may be disposed lower than the bottom end of the gate insulating layer (131).

In addition, according to the embodiment, the ion implantation connection region of the second conductivity type (121U) may connect the extended second well of the second conductivity type (124E) and the first well of the second conductivity type (121).

Accordingly, the first well of the second conductivity type (121) to which the ground potential is applied can be connected to the extended second well of the second conductivity type (124E) by the ion implantation connection region of the second conductivity type (121U), so that the extended second well of the second conductivity type (124E) may also be applied with the ground potential.

Meanwhile, in the internal technology, research was conducted to place a bottom P-well under the trench to prevent electric field concentration at the trench corner.

First, a ‘floating bottom P-well’ was formed in a floating state separated from the trench gate and gate insulation layer using the first internal technology.

This ‘floating bottom P-well’ has the effect of alleviating the electric field concentration at the trench corner and preventing the breakdown voltage drop, but the problem that the potential around the floating bottom P-well is affected by the continuous and repeated charging and discharging inside the floating bottom P-well was studied.

In other words, the problem that an unknown internal potential occurs in the floating bottom P-well in addition to the external potential applied adversely affects the electrical characteristics of the power semiconductor device was studied. In addition, the floating bottom P-well has the problem that the ON resistance (Ron/R_{DS}), which is the resistance between the drain and the source, increases by interfering with the current flow in the ON state.

Next, a ‘contact bottom P-well’ was formed at the bottom of the trench to contact the trench gate insulating layer using the second internal technology.

However, when the ‘contact bottom P-well’ is formed at the bottom of the trench to contact the trench gate insulating layer, there is an effect of alleviating the electric field concentration at the trench corner. But there was a problem that the width of the depletion layer increased depending on the drain voltage in the ‘contacted lower P-well’ in contact with the gate insulating layer, resulting in a deterioration in the forward current characteristics.

In addition, when the ‘contact bottom P-well’ is formed close to the P-base (P-well) to contact the trench gate insulating layer, the problem of the JFET resistance occurring between the P-base (P-well) and the contacted bottom P-well, which increases the ON resistance (Ron), was studied.

On the other hand, referring to FIG. 13, in the embodiment, the ion implantation connection region of the second conductivity type (121U) may connect the extended second well of the second conductivity type (124E) and the first well of the second conductivity type (121). Accordingly, the first well of the second conductivity type (121) to which the ground potential is applied can be connected to the extended second well of the second conductivity type (124E) by the ion implantation connection region of the second conductivity type (121U), so that the extended second well of the second conductivity type (124E) may also be applied with the ground potential.

Therefore, according to the embodiment, since the ground potential can be applied to the extended second well of the second conductivity type (124E) to prevent electric field concentration at the trench corner, the occurrence of a depletion region in the extended second well of the second conductivity type (124E) can be prevented, thereby preventing an increase in the On-resistance (Ron).

In addition, since the ground potential is applied to the extended second well of the second conductivity type (124E) to prevent electric field concentration at the trench corner, the extended second well of the second conductivity type (124E) may not be in a floating state, so that there is no charging and discharging phenomenon of the extended second well of the second conductivity type (124E), so that there is a technical effect that enables stable operation in a dynamic situation or a switching situation.

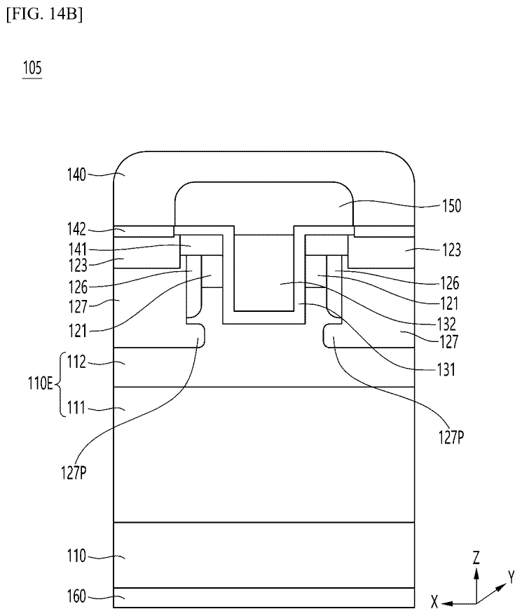

Next, FIG. 14A is a cross-sectional view of the fourth power semiconductor device (104) according to the embodiment.

The fourth power semiconductor device (104) according to the embodiment may adopt the technical features of the first power semiconductor device (101) to the third power semiconductor devices (101, 102, 103), and the main features of the fourth power semiconductor device (104) will be described below.

The fourth power semiconductor device (104) according to the embodiment may include at least one of a drain electrode (160), a substrate (110), an epi layer (110E), a first well of the second conductivity type (121), a contact region of the second conductivity type (123), a high concentration third well of the second conductivity type (125), a source region of the first conductivity type (141), a source contact region (142), a source electrode (140), a gate insulating layer (131), a trench gate (132), and an interlayer insulating layer (150).

The fourth power semiconductor device (104) may further include a deep fifth well of the second conductivity type (127). In addition, the deep fifth well of the second conductivity type (127) may include an extended deep fifth well of the second conductivity type (127P) extending in the trench edge direction.

According to the fourth power semiconductor device (104) according to the embodiment, a high-concentration third well of the second conductivity type (125) having a higher concentration than the contact region of the second conductivity type (123) may be included. Accordingly, the fourth power semiconductor device (104) may prevent Reach Through BV occurring in the second conductivity type region that is not covered by the lower P-well. n addition, according to the fourth power semiconductor device (104), by including a deep fifth well of the second conductivity type (127) having an extended deep fifth well of the second conductivity type (127P), Reach Through BV occurring in the second conductivity type region may be effectively prevented.

Next, FIG. 14B is a cross-sectional view of a fifth power semiconductor device (105) according to an embodiment.

The fifth power semiconductor device (105) according to an embodiment may adopt the technical features of the first power semiconductor device (101) to the fourth power semiconductor devices (101, 102, 103, 104), and the main features of the fifth power semiconductor device (105) will be described below.

The fifth power semiconductor device (105) according to the embodiment may include at least one of a drain electrode (160), a substrate (110), an epi layer (110E), a first well of the second conductivity type (121), a contact region of the second conductivity type (123), an extended high concentration fourth well of the second conductivity type (126), a source region of the first conductivity type (141), a source contact region (142), a source electrode (140), a gate insulating layer (131), a trench gate (132), and an interlayer insulating layer (150).

The fifth power semiconductor device (105) may further include a deep fifth well of the second conductivity type (127). The deep fifth well of the second conductivity type (127) may include an extended deep fifth well of the second conductivity type (127P) extending in the trench edge direction.

The fifth power semiconductor device (105) may include an extended high-concentration fourth well of the second conductivity type (126) formed by extending to the first well of the second conductivity type (121) and the epilayer of the first conductivity type (110E). The extended high-concentration fourth well of the second conductivity type (126) may have a higher doping concentration than the contact region of the second conductivity type (123). Accordingly, according to the fifth power semiconductor device (105), by including the extended high-concentration fourth well of the second conductivity type (126) having a higher concentration than the contact region of the second conductivity type (123), Reach Through BV occurring in the region of the second conductivity type may be more effectively prevented.

Also, according to the fifth power semiconductor device (105), by including a deep fifth well of the second conductivity type (127) having an extended deep fifth well of the second conductivity type (127P), it is possible to effectively prevent Reach Through BV occurring in the second conductivity type region.

Although the present invention has been described above with reference to embodiments, it will be readily understood by those skilled in the art that the present invention may be variously modified and changed within the scope of the invention described in the following claims.

What is claimed is:

1. A power semiconductor device, comprising:
a substrate on a drain electrode;
a first epi layer of a first conductivity type disposed on the substrate;
a second epi layer of the first conductivity type disposed on the first epi layer of the first conductivity type;
a first well of a second conductivity type disposed on the second epi layer of the first conductivity type;
a source region of the first conductivity type disposed on the first well of the second conductivity type;
a gate insulating layer configured to penetrate from the source region of the first conductivity type to a part of the second epi layer of the first conductivity type and to form a trench region therein;
a trench gate disposed in the trench region; and
an extended second well of the second conductivity type disposed in the second epi layer of the first conductivity type below the gate insulating layer with a width equal to or equal to or greater than that of the trench region.

2. The power semiconductor device according to claim 1, further comprising a contact region of the second conductivity type disposed on the first well of the second conductivity type.

3. The power semiconductor device according to claim 2, wherein the extended second well of the second conductivity type is doped with a concentration lower than or equal to the contact region of the second conductivity type.

4. The power semiconductor device according to claim 3, wherein the extended second well of the second conductivity type is disposed in a continuous form along the trench region.

5. The power semiconductor device according to claim 4, wherein the extended second well of the second conductivity type is disposed to extend parallel to a first direction which is an extension direction of the trench gate.

6. The power semiconductor device according to claim 2, further comprising a high-concentration third well of the second conductivity type disposed within the first well of the second conductivity type.

7. The power semiconductor device according to claim 5, wherein the high-concentration third well of the second conductivity type is disposed at a bottom of the contact region of the second conductivity type.

8. The power semiconductor device according to claim 7, wherein the high-concentration third well of the second conductivity type has a higher doping concentration than the contact region of the second conductivity type.

9. The power semiconductor device according to claim 6, wherein the high-concentration third well of the second conductivity type is disposed spaced apart from the gate insulating layer and the trench gate.

10. The power semiconductor device according to claim 2, further comprising an extended high-concentration fourth well of the second conductivity type disposed at the bottom of the contact region of the second conductivity type.

11. The power semiconductor device according to claim 10, wherein the extended high-concentration fourth well of the second conductivity type is configured to extend to the first well of the second conductivity type and the epi layer of the first conductivity type.

12. The power semiconductor device according to claim 10, wherein the extended high-concentration fourth well of the second conductivity type has a higher doping concentration than the contact region of the second conductivity type.

13. The power semiconductor device according to claim 12, wherein a bottom end of the extended high-concentration fourth well of the second conductivity type is disposed lower than that of the first well of the second conductivity type.

14. The power semiconductor device according to claim 2, further comprising an ion implantation connection region of the second conductivity type disposed to extend in a second direction perpendicular to the first direction while connecting the extended second well of the second conductivity type disposed horizontally in the first direction.

15. A power semiconductor device, comprising:
a substrate on a drain electrode;
a first epi layer of a first conductivity type disposed on the substrate;
a second epi layer of the first conductivity type disposed on the first epi layer of the first conductivity type;
a first well of a second conductivity type disposed on the second epi layer of the first conductivity type;
a source region of the first conductivity type disposed on the first well of the second conductivity type;
a gate insulating layer disposed to penetrate from the source region of the first conductivity type to a part of the second epi layer of the first conductivity type and form a trench region therein;
a trench gate disposed in the trench region;
a contact region of the second conductivity type disposed on the first well of the second conductivity type; and
a deep fifth well of the second conductivity type disposed below the contact region of the second conductivity type and having a bottom end lower than a bottom of a trench region.

16. The power semiconductor device according to claim 15, wherein the deep fifth well of the second conductivity type comprises an extended deep fifth well of the second conductivity type extending from a bottom end of the deep fifth well of the second conductivity type to the trench region.

17. A power convertor comprising the power semiconductor device according the claim 1.
